(19) United States
(12) Patent Application Publication
(10) Pub. No.: US 2011/0080176 A1
(43) Pub. Date: Apr. 7, 2011

(54) PART OF A VEHICLE AND VEHICLE COMPRISING SUCH PART

(75) Inventors: Marie-Laure HOPDJANIAN, Toulouse (FR); Pierre Calvairac, Fonsorbes (FR)

(73) Assignee: Airbus Operations (S.A.S.), Toulouse Cedex (FR)

(21) Appl. No.: 12/891,194

(22) Filed: Sep. 27, 2010

(30) Foreign Application Priority Data
Oct. 2, 2009 (FR) 09 56906

(51) Int. Cl. G01R 31/00

(52) U.S. Cl. 324/503

(57) ABSTRACT

It concerns a vehicle part comprising electric cables (4) adapted for conveying an electric current from at least one generator (2), with the said electric cables (4) that comprise at least one phase cable (40) associated with a phase of the generator, and comprising a short-circuit detection device (5) comprising measurement means (8) adapted for cooperating with the said phase cable (40).

The electric cables further comprise a neutral cable (41), the detection device (5) comprising on the one hand the current measurement means (8), that are further adapted for cooperating with the said neutral cable (41), and on the other hand a control and calculations unit (9) connected to the said current measurement means and adapted for comparing with a determined threshold a value representative of the resultant of the currents circulating respectively in the said electric cables (4).

This invention relates to a vehicle part comprising electric cables adapted for conveying electric current from at least one generator, and in particular in an aircraft.

There already are known aircraft the electric network of which comprises electric generators, in particular at the wings of the aircraft near the jet engines, and an electric power center distributing the electric power delivered by the generators, the electric power center being located in the fuselage of the aircraft.

Phase cables extend from each of the generators up to the electric power center, passing through the fuselage and/or the wings.

In order to protect the aircraft against a short-circuit fault in one of the phase cables, it is known to implement a differential protective function.

FIG. 3 shows such a protective device for cables according to the prior art, in which a first measurement of the currents circulating in the three phase cables 104 is made, this first measurement being performed at the output of each generator 102. These currents are measured, for example, by measurement means 108a comprising at least one current transformer.

A second measurement also is made of the currents circulating in the three phase cables 104 at the input of electric power center 103. These currents also are measured by measurement means 108b for example comprising at least one current transformer.

The first and second current measurements are routed by current measurement cables 110a, 110b to a control and calculation unit 109.

The device then verifies that the difference between the current measurement at the generator and the measurement at the electric power center does not exceed a limit value (for example 50 A for 50 ms for certain aircraft) on one of the phases.

If there is no fault, the difference between the two measurements points for each of the phase cables is nil.

If there is a short-circuit fault, the limit value is exceeded, and a control module 112 of the generator, present in unit 109, interrupts the generation of power by the said generator.

In known manner, it is the metal structure of the aircraft that ensures the continuity of the electric neutral from the generator, connected to the structure in a nacelle, up to the electric power center.

A vehicle part comprising cables and a protective device as mentioned above has the drawback of requiring, since the measurement devices take two current measurements for the same cable at different points, perfectly matched measurement devices in order to have identical dynamic responses and not resulting in any measurement deviation likely to activate the protection.

Moreover, the current measurement cables require dedicated paths and a special risk analysis, since a break in these measurement cables leads to activation of the protection and to loss of the associated generator. These specific paths are difficult to route in the aircraft by reason of the high density of electric cable circulating in the aircraft, and in particular for the measurement cables associated with the measurement performed at the output of the generator, which is performed at a distance from the control and calculation unit and which involves long cable routes.

There furthermore is known a design for such vehicles according to which the metal structures are replaced by structures made of composite material. In these structures, it is contemplated to cable the neutral of the generators up to the electric power center without passing through the structure, which involves providing a protective system adapted to the presence of this cable.

The invention intends to supply a vehicle part comprising cables and a short-circuit detection device that is particularly economical and simple to produce.

To this end it proposes a vehicle part comprising electric cables adapted for conveying an electric current from at least one generator, with the said electric cables that comprise at least one phase cable associated with a phase of the generator, and comprising a short-circuit detection device comprising measurement means adapted for cooperating with the said phase cable, characterized in that the electric cables further comprise a neutral cable, the detection device comprising on the one hand current measurement means, that are further adapted for cooperating with the said neutral cable, and on the other hand a control and calculations unit connected to the said current measurement means and adapted for comparing with a predetermined threshold a value representative of the resultant of the current circulating respectively in the said electric cables.

In the vehicle part according to the invention, the neutral of the generator is cabled and this neutral cable is used by a short-circuit detection device common to the phase cables of this generator.

The fact that the neutral is cabled in the vehicle makes it possible to measure the current values for the three phases and for the neutral simultaneously, and to immediately deduce therefrom whether a short-circuit current is present in the structure of the vehicle.

The invention also proposes a vehicle comprising a vehicle part such as described above and comprising an electric power center adapted for distributing the electric power received from the said generator, with the phase cable and the neutral cable that extend between the generator and the electric power center, the current measurement means being connected to the phase cable at a sole measurement point along the said phase cable, and to the neutral cable at a sole measurement point along the said neutral cable.

Current measurement at a sole point along the cables makes it possible to reduce the number of current measurement means required, thus making the detection device particularly convenient to install and advantageous in terms of weight, cost and reliability.

According to one characteristic of the invention, the current measurement means are disposed in the electric power center in the vicinity of the control and calculations unit.

The detection device thus is located in its entirety in the electric power center, and does not result in the presence of cable routes that extend into the vehicle.

According to another characteristic of the invention, the current measurement means are adapted for measuring individually the current in the phase cable and in the neutral cable, the control and calculations unit being adapted for adding the measured current values and for comparing the sum obtained with the said determined threshold.

These individual measurements of the currents circulating respectively in the phase cables make it possible to detect short circuits and further make it possible to detect any output fault of the associated generator in the event of a total cut-off of the phases of the generator.

According to other characteristics of the invention:
the electric current conveyed from the generator comprises three phases, so that the electric cables comprise three phase cables and the neutral cable, the current measurement means being connected electrically to the said three phase cables and to the said neutral cable, the control and calculations unit being adapted for comparing with the determined threshold a value representative of the resultant of the four currents circulating respectively in the said electric cables;
the current measurement means are adapted for measuring individually the current in each of the three phase cables and in the neutral cable, the control and calculations unit being adapted for adding the four measured current values and for comparing the sum obtained with the determined threshold;
the current measurement means comprise current transformers, with a current transformer associated with each electric cable;
the structure of the vehicle is made of composite material; and
the vehicle is an aircraft.

Finally, the invention protects an aircraft the electric power center, the current measurement means and the control computer of which are disposed in the avionic bay, in the forward cone of the aircraft.

According to other characteristics of the invention:
the aircraft comprises current measurement means adapted for cooperating with the electric cables upstream from the said electric power center; and/or
the aircraft comprises at least four generators disposed in the wings of the aircraft and an auxiliary generator in the tail cone of the fuselage of the aircraft, each generator being connected to the electric power center by at least one phase cable and a neutral cable, current measurement means being associated with each generator, and all the current measurement means being connected to the control and calculation unit.

The exposition of the invention now will be continued with the detailed description of exemplary implementations, presented below by way of non-limitative illustration, with reference to the attached drawings, on which:

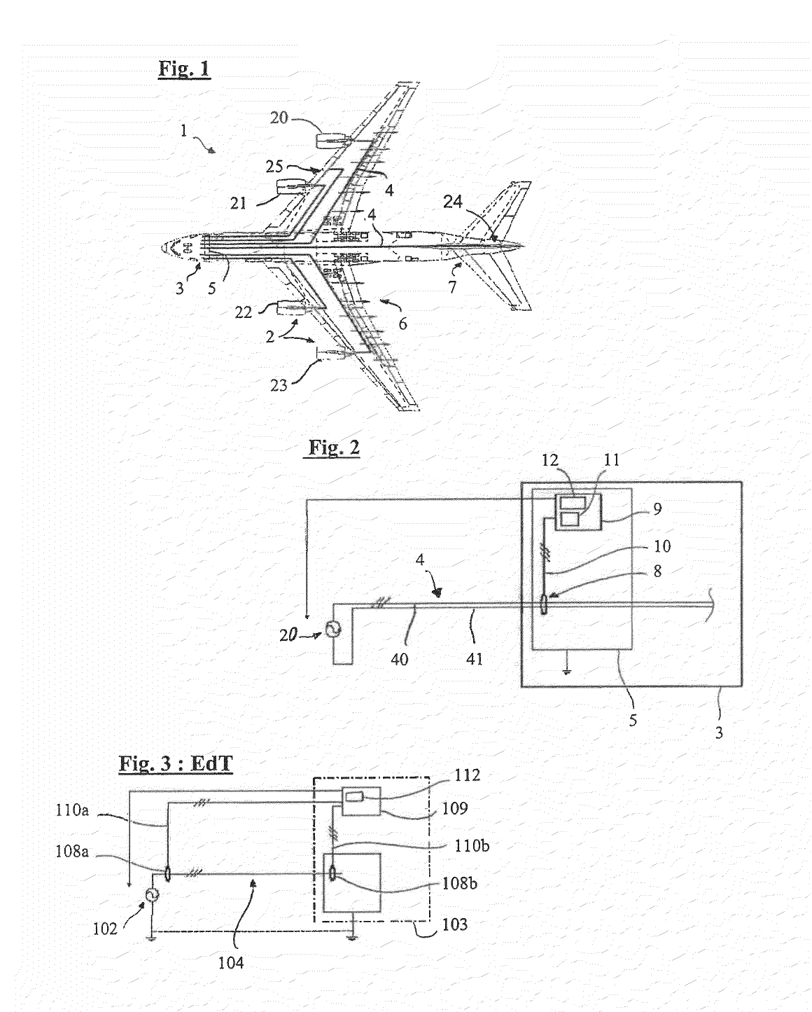

FIG. 1 is a representation of an aircraft comprising cables adapted for connecting generators and an electric power center;

FIG. 2 is a diagram representative of the invention, in which phase cables and a neutral cable extend between a generator and the electric power center of the vehicle, with measurement means that are connected to the phase cables and to the neutral cable at a sole measurement point along these cables; and

FIG. 3 is a diagram representative of the teaching of the state of the art, in which phase cables and a neutral cable extend between a generator and the electric power center of the vehicle, with measurement means that are disposed in two current measurement zones.

Hereinafter, an aircraft part comprising cables and a short-circuit detection device is described. It will be understood that other vehicles, such as a train, an automotive vehicle or a ship could have been described, without departing from the context of the invention, so long as it is wished to protect the cables from a short-circuit in such vehicle.

As illustrated on FIG. 1, an aircraft 1 comprises generators 2, an electric power center 3 and electric cables 4 that extend between each of generators 2 and center 3. Aircraft 1 further comprises a short-circuit detection device 5 disposed in electric power center 3.

Here, the structure of aircraft 1 is made of composite material.

Electric generators 2 comprise four generators 20, 21, 22, 23 disposed at the wings 6 and driven by the motors, a generator 24 disposed in tail cone 7 of the fuselage and driven by an auxiliary motor unit (called APU), and here an emergency generator 25 also disposed at wings 6.

These generators 2 here are triphase current generators.

Electric power center 3, adapted for distributing the electric power coming from the generators, here is located in the forward cone of the aircraft, in a zone commonly called the avionic bay. It will be understood that, without departing from the context of the invention, the electric power center may be located in a central section of the aircraft.

Electric cables 4 comprise phase cables 40, here three in number, and a neutral cable 41, as may be seen on FIG. 2.

Phase cables 40, associated respectively with each of the phases of each generator 2, extend from wings 6, or from tail cone 7, up to electric power center 3.

Neutral cable 41 connects the neutral of each generator 2 to the neutral of electric power center 3.

It will be observed that, according to the invention, neutral cable 40 is present irrespective of the structure of the aircraft, in particular a metal structure or a structure, as described above, made of composite material.

As illustrated on FIG. 2, detection device 5 comprises measurement means 8 and a control and calculations unit 9. Such a detection device 5 is provided for each set of electric cables 4 here comprising three phase cables 40 and a neutral cable 41, and which extends between electric power center 3 of the aircraft and one of the generators 2.

The description that is going to follow is set forth for a detection device associated with a generator 20 and with electric cables that connect this generator 20 to electric power center 3, but it will be understood that similar detection devices advantageously may be provided for each of the generators in the aircraft.

Current measurement means 8 here make an individual measurement of the current in each of the three phase cables 40 and neutral cable 41.

As may be seen on FIG. 2, current measurement means 8 are adapted for cooperating with phase cables 40 and neutral cable 41, at a sole measurement point along each of these cables between the generator and the electric power center.

Means 8 here comprise current transformers, with a current transformer associated with each cable.

Current measurement means 8 and control and calculations unit 9 are connected by current measurement cables 10, with a current measurement cable 10 associated with each phase cable 40 and with neutral cable 41.

It will be observed that according to the invention, a sole measurement cable 10 is associated with each electric cable 4 by reason of the measurement at a sole point along each of the cables.

Current measurement means 8 and control and calculations unit 9 are disposed in the electric power center, with measurement means 8 which are in the vicinity of unit 9. In that way, the length of current measurement cables 10 therefore is reduced.

Control and calculations unit 9 comprises a calculations module 11 and a control module 12.

Calculations module 11 receives, through current measurement cable 10, a value representative of the resultant of the currents circulating in the cables.

Here, in the described example of an individual measurement of currents, calculations module 11 is programmed first to produce the sum of the measured current values, each value being able to be positive or negative depending on the direction of circulation of these currents. Calculations module 11 subsequently compares the sum obtained with a determined threshold, for a set time.

Without a circuit fault, the sum of the four currents circulating in three phase cables 40 and neutral cable 41 is in theory nil, therefore lower than the determined threshold. The value of the threshold is determined so that minor oscillations around this theoretical nil value are not taken as short-circuit faults.

If there is a short-circuit fault that comes to be added to the four measured currents, the sum of the currents exceeds the threshold determined for the set time.

Calculations module 11 thus compares the sum with the determined threshold and transmits to control module 12 an information item according to which the line of cables has a short-circuit fault as soon as the sum is above the determined threshold for the set time.

Control module 12 here is connected directly to generator 20, so that, in response to such an information item of detection of a short-circuit in generator 20, it may generate a control of this generator in order to isolate it electrically, for example.

In this way, according to the invention, the study of the resultant of the currents circulating respectively in the cables and the placement of current measurement at a sole point along each electric cable of a given generator allows the detection of a short-circuit current and allows an immediate operation of the control module on the generator concerned. This short-circuit detection thus has the advantage of requiring only a limited number of current measurement means and current measurement cables, in this way making the detection device particularly convenient to install, with achievement of a reduced increase of weight in the vehicle and a reduced installation and maintenance cost. Moreover, this limited number of components ensures a heightened reliability of the detection device.

According to other variants not shown:
the network is not triphase, but monophase: only two cables extend between each generator and the electric power center with a neutral cable and a phase cable; the principle of the invention is the same with current measurement means that measure the values of the current in the two cables and the control and calculation unit that verifies that the sum of the currents is more or less nil;
the control module is not connected directly to the generator, but through an electric component that transmits the order of feed supplied by the control module to the generator;
the current measurement means are disposed upstream from the electric power center; and/or
the current measurement means do not make individual measurements of each of the three phase cables and the neutral cable; the current measurement cables associated with each phase and with the neutral are wound around a torus; without short-circuit current, the sum of the currents circulating in the wound cables being theoretically nil, there is no resultant magnetic flux; if the currents do not cancel each other out, a magnetic field is generated and this information is transmitted to the control and calculation unit which compares the value of this field to a threshold.

It will be noted that, in the event of a total cut-off on the 3 phases, the sum of the measured currents is nil and no short-circuit current is detected; an individual measurement of the currents then makes it possible to find that there is an output fault in one of the generators.

It will be observed that according to the invention, the current measurement at the output of the generator has been eliminated, which represents on the one hand a gain by reason of the reduction of the number of cables and the number of measurement devices to be provided, and which represents on the other hand an optimized functioning without untimely activation due to a disparity in adjustment of the different measurement devices for the same generator.

Of course, numerous modifications may be introduced in the exemplary implementation described above without departing from the context of the invention.

1. Vehicle part comprising electric cables (4) adapted for conveying an electric current from at least one generator (2), with the said electric cables (4) that comprise at least one phase cable (40) associated with a phase of the generator (2), and comprising a short-circuit detection device (5) comprising measurement means (8), adapted for cooperating with the said phase cable (40), characterized in that the electric cables (4) further comprise a neutral cable (41), the detection device (5) comprising on the one hand current measurement means (8), that are further adapted to cooperating with the said neutral cable (41), and on the other hand a control and calculations unit (9) connected to the said current measurement means (8) and adapted for comparing with a determined threshold a value representative of the resultant of the currents circulating respectively in the said electric cables (4).

2. Vehicle comprising a part according to claim 1, characterized in that it comprises an electric power center (3) adapted for distributing the electric power received from the said generator (2), with the phase cable (40) and the neutral cable (41) that extend between the generator (2) and the electric power center (3), the current measurement means (8) being connected to the phase cable (40) at a sole measurement point along the said phase cable (40), and to the neutral cable (41) at a sole measurement point along the said neutral cable (41).

3. Vehicle according to claim 2, characterized in that the current measurement means (8) are disposed in the electric power center (3) in the vicinity of the control and calculations unit (9).

4. Vehicle according to one of claim 2 or 3, characterized in that the current measurement means (8) are adapted for measuring individually the current in the phase cable (40) and in the neutral cable (41), the control and calculations unit (9) being adapted for adding the measured current values and for comparing the sum obtained with the said determined threshold.

5. Vehicle according to one of claim 2 or 3, characterized in that the electric current conveyed from the generator (2) comprises three phases, so that the electric cables (4) comprise three phase cables (40) and the neutral cable (41), and that the current measurement means (8) are connected electrically to the said three phase cables (40) and to the said neutral cable (41), the control and calculations unit (9) being adapted for comparing with the determined threshold a value representative of the resultant of the four currents circulating respectively in the said electric cables (4).

6. Vehicle according to the preceding claim, characterized in that the current measurement means (8) are adapted for measuring individually the current in each of the three phase cables (40) and in the neutral cable (41), the control and calculations unit (9) being adapted for adding the four measured current values and for comparing the sum obtained with the determined threshold.

7. Vehicle according to claim 6, characterized in that the current measurement means (8) comprise current transformers, with a current transformer associated with each electric cable (4).

8. Vehicle according to one of claims 2 to 7, characterized in that the structure of the vehicle is made of composite material.

9. Vehicle according to one of claims 2 to 8, characterized in that the vehicle is an aircraft.

10. Aircraft according to claim 9, characterized in that the electric power center (3), the current measurement means (8) and the control and calculations unit (9) are disposed in the avionic bay, in the forward cone of the aircraft.
